(19) United States
(12) Patent Application Publication
(10) Pub. No.: US 2024/0356509 A1
(43) Pub. Date: Oct. 24, 2024

(54) FAST SWITCHING AND ULTRA-LOW POWER COMPACT VARACTOR DRIVER

(71) Applicant: TTM Technologies, Inc., Santa Ana, CA (US)

(72) Inventors: Yi Zhang, East Northport, NY (US); Zhigang Ma, Allentown, PA (US)

(21) Appl. No.: 18/641,063

(22) Filed: Apr. 19, 2024

Related U.S. Application Data
(60) Provisional application No. 63/460,554, filed on Apr. 19, 2023.

(51) Int. Cl. H03F 3/45; H03F 1/26

(52) U.S. Cl. CPC H03F 3/45475; H03F 1/26; H03F 3/45273; H03F 2200/261

(57) ABSTRACT

A varactor driver for driving a varactor diode load may include a first switch controlled by a control signal, and a second switch controlled by the same control signal. The varactor driver may be configured to operate in a tracking mode when the first switch and the second switch are tuned on and to operate in a holding mode when the first switch and the second switch are tuned off. The varactor driver may also include an operational amplifier connected with the second switch in parallel. The operational amplifier is configured to be a unity gain buffer. The varactor driver may also include a capacitor configured to operate in the holding mode to provide a holding-voltage as an output voltage.

### CROSS-REFERENCE TO RELATED PATENT APPLICATIONS

This patent application claims the benefit under 35 U.S.C. § 119(e) of U.S. Patent Application Ser. No. 63/460,554, entitled “A Fast Switching, Ultra-Low Power and Compact Varactor Driver,” filed on Apr. 19, 2023, which is incorporated herein by reference in its entirety.

### BACKGROUND

A varactor-diode driver is commonly used as a voltage-controlled capacitor and is suitable for operation in reverse bias conditions. Existing varactor drivers, however, often use conventional track and hold circuit that may consume excessive power in operation.

### BRIEF SUMMARY

In one aspect, a varactor driver for driving a varactor diode load may include a first switch controlled and a second switch controlled by a control signal. The varactor driver may be configured to operate in a tracking mode when the first switch and the second switch are tuned on and to operate in a holding mode when the first switch and the second switch are tuned off. The varactor driver may also include an operational amplifier connected with the second switch in parallel. The operational amplifier is configured to be a unity gain buffer. The varactor driver may also include a capacitor configured to operate in the holding mode to provide a holding-voltage as an output voltage.

In some aspects, the varactor driver may be CMOS based.

In some aspects, the first switch may include a NMOS transistor and a PMOS transistor connected back-to-back.

In some aspects, the NMOS transistor may have a gate driven by the first control signal. The PMOS transistor may have a gate driven by the second control signal inverted from the first control signal.

In some aspects, the unity gain buffer may include a non-inverting input terminal, an inverting input terminal, an output terminal, a power supply terminal, and a ground terminal.

In some aspects, the non-inverting input terminal may connect to the capacitor, the first switch, and the second switch.

In some aspects, the output terminal may connect to the varactor diode.

In some aspects, the power supply terminal may connect to a power supply source, wherein the ground terminal connects to ground.

In some aspects, the operational amplifier may be configured to be the unity gain buffer by connecting the inverting input terminal to the output terminal.

In some aspects, the varactor diode may have a voltage droop that is compensated by the unity gain buffer.

In some aspects, the varactor driver may have a power consumption equal to or less than 20 μW excluding bias and loading.

In some aspects, the varactor driver may have a fast response with an RC time constant equal to or less than 3 μs.

In some aspects, the operational amplifier may be constructed using CMOS technology.

In some aspects, the varactor driver array may include two or more varactor drivers.

In some aspects, a system may include the varactor driver, a controller coupled to the varactor driver to provide the control signal to the first switch and the second switch, a power source coupled to the unity gain buffer, and a signal source coupled to the varactor driver through the first switch to provide an input voltage to the varactor driver.

In some aspects, a method may include responding to a first tracking request including performing operations (1) and (2) as follows: (1) closing the first switch and the second switch, by using the controller, to operate the varactor driver in the tracking mode, wherein the second switch shorts the operational amplifier to provide a lowest resistance path to bypass the operational amplifier such that the driver has a reduced RC time constant and a reduced response time; and (2) opening the first switch and the second switch, by using the controller, to operate the varactor driver in the holding mode, wherein the driver is in a steady state.

In some aspects, the first switch and the second switch are closed or turned “ON” in the tracking mode such that the output voltage equals to the input voltage in the tracking mode, wherein the first switch and the second switch are open or turned “off” in the holding mode such that the output voltage equals to the holding-voltage on the capacitor sampled from a previous track-hold cycle, wherein the unity gain buffer is fully active in the holding mode and less active in the tracking mode.

In some aspects, the method may also include responding to a second tracking request by repeating operations (1) and (2) succeeding the first tracking request after a first period of time, wherein in the holding mode, the output voltage equals to the holding-voltage on the capacitor in the first tracking request.

In some aspects, the method may also include responding to a third tracking request by repeating operations (1) and (2) succeeding the second tracking request after a second period of time, wherein in the holding mode, the output voltage equals to the holding-voltage on the capacitor in the second tracking request.

In some aspects, the second period of time may equal to the first period of time.

In some aspects, the varactor diode may be configured to be reversely biased.

Additional aspects and features are set forth in part in the description that follows and will become apparent to those skilled in the art upon examination of the specification or may be learned by the practice of the disclosed subject matter. A further understanding of the nature and advantages of the disclosure may be realized by reference to the remaining portions of the specification and the drawings, which form a part of this disclosure.

### BRIEF DESCRIPTION OF THE DRAWINGS

The description will be more fully understood with reference to the following figures and data graphs, which are presented as various embodiments of the disclosure and should not be construed as a complete recitation of the scope of the disclosure, wherein:

FIG. 1 is a diagram of a system including varactor driver and varactor diode according to one aspect of the disclosure;

FIG. 2A illustrates a configuration of the varactor driver of FIG. 1 for operation in a tracking mode of operation according to one aspect;

FIG. 2B illustrates a configuration of the varactor driver of FIG. 1 for operation in a holding mode of operation according to one aspect;

FIG. 3 illustrates a circuit diagram of a switch including NMOS and PMOS transistors according to one aspect;

FIG. 4 illustrates a circuit diagram of the varactor driver for implementation of the operation of the tracking mode of FIG. 2A and the holding mode of FIG. 2B according to one aspect;

FIG. 5 is a circuit diagram of the operational amplifier of FIG. 4 according to one aspect;

FIG. 6A is a graph of voltage versus time illustrating the operation of the varactor driver of FIG. 4 according to one aspect;

FIG. 6B is a graph of enlarged view of the voltage versus time of FIG. 6A according to one aspect; and

FIG. 7 is a system diagram including an array of the varactor drivers of FIG. 1 according to one aspect.

### DETAILED DESCRIPTION

The disclosure may be understood by reference to the following detailed description, taken in conjunction with the drawings as described below. It is noted that, for purposes of illustrative clarity, certain elements in various drawings may not be drawn to scale.

The disclosures of these patents, patent applications, and publications in their entireties are hereby incorporated by reference into this application to more fully describe the state of the art as known to those skilled therein as of the date of the invention described and claimed herein.

The instant disclosure will govern in the instance that there is any inconsistency between the patents, patent applications, and publications and this disclosure.

Unless defined otherwise, all technical and scientific terms used herein have the same meaning as commonly understood by one of ordinary skill in the art to which this disclosure belongs. The initial definition provided for a group or term herein applies to that group or term throughout the present specification individually or as part of another group unless otherwise indicated.

To explain the invention well-known features of complementary metal-oxide-semiconductor (CMOS) technology known to those skilled in the art of integrated circuit design have been omitted or simplified in order not to obscure the basic principles of the invention. Parts of the following description will be presented using terminology commonly employed by those skilled in the art of CMOS technology. It should also be noted that in the following description of the invention repeated usage of the phrase “in one embodiment” does not necessarily refer to the same embodiment.

### Definitions

“CMOS technology” uses CMOS circuitry or CMOS circuits and CMOS processes to implement the CMOS circuitry on integrated circuits or chips. The CMOS circuits use a combination of p-type and n-type MOSFETs to implement analog circuit, logic gates and other digital circuits. CMOS is generally considered as a low power technology.

An “integrated circuit”, also known as a microchip, chip or IC, is a small electronic device made up of multiple interconnected electronic components such as transistors, resistors, and capacitors. These components are integrated onto a small piece of semiconductor material, usually silicon.

“Varactors” are voltage-controlled capacitors.

A “varactor diode” is a type of diode designed to exploit the voltage dependent capacitance of a reverse-biased p-n junction. The varactor diode's capacitance varies with the applied reverse voltage, and is used as a voltage-controlled capacitor. The P-N junction is a boundary or interface between two types of semiconductor materials, p-type and n-type.

An “operational amplifier” is an integrated circuit that amplifies the difference in voltage between two inputs. The word “operational” is used because the amplifier can perform arithmetic operations with the help of external components. The operational amplifier is also referred to as “CMOS amplifier”, “CMOS unity gain amplifier”, “CMOS unity gain buffer”, “voltage buffer” in the application.

A “unity gain buffer” is a configuration of the operational amplifier. The output voltage (VOUT) is matched to the input voltage (VIN) applied to the non-inverting input terminal of the operational amplifier. The gain (VOUT/VIN) of the unity gain buffer is 1.

“Voltage droop” defines the VOUT voltage loss as the varactor driver drives the varactor diode load. Such voltage loss is mainly due to the current leakage of the varactor diode. In the related application, it is defined as the percentage of VOUT initial value over a period of time. For example, in a particular application in which the disclosed varactor driver may be used in an electronically steered, flat-panel satellite terminal for fixed and mobile platforms, among other uses, the period of time may be 300 μs.

The present disclosure addresses the problems of conventional varactor drivers, such as the use of excessive power, having large voltage droops. Conventional varactor drivers rely on the voltage buffer in operation, dissipating power supply (VDD) current (Ivdd).

The present disclosure provides a varactor driver that is capable of operating at ultra-low power (e.g., 1 μA at 20 V) without compromising the performance. The varactor driver includes two control switches, one switch for a voltage-holding capacitor, and one switch for a unity gain buffer. The switches control the operation of the varactor driver into two modes, e.g., a tracking mode and a holding mode. In the tracking mode, the varactor driver is driven directly from the signal source, through a low resistive pass (e.g., closed switches), while the unit gain buffer is bypassed and less active. In the holding mode, the unity-gain buffer operates to maintain an output voltage following the pre-sampled voltage from the voltage-holding capacitor. Since the unity gain buffer is mostly active in the holding mode, and the holding mode is in a steady state (DC) operation, such that the power dissipation of the unity gain buffer is reduced. In addition, the varactor driver also has a few components, which allows a compact die area for the circuit implementation.

The present disclosure provides a complementary metal-oxide-semiconductor (CMOS) technology-based varactor driver for driving a varactor diode to achieve low voltage droops and fast response. The varactor driver includes a first switch and a second switch both controlled by a control signal. The varactor driver is configured to operate in a tracking mode when the first switch and the second switch are tuned on and to operate in a holding mode when the first switch and the second switch are tuned off. The varactor driver also includes an operational amplifier connected with the second switch in parallel, wherein the operational amplifier is configured to be a unity gain buffer. The varactor driver further includes a voltage-holding capacitor configured to operate in the holding mode to provide a holding-voltage as an output voltage.

In some aspects, varactor driver may include a secondary CMOS switch connected in parallel with a CMOS unity gain buffer or CMOS unity gain amplifier.

The disclosed varactor driver is different from the convention varactor driver, which does not include the secondary CMOS switch. The disclosed varactor driver reduces the power dissipation of the conventional varactor driver by only fully utilizing the CMOS unity gain buffer in a holding mode, which is a low power mode because the input of the CMOS unity gain buffer remains constant.

By way of example and not limitation, the varactor driver may be used in a tracking operation and in a holding operation. According to one aspect, during the tracking operation, both the primary and secondary CMOS switches are turned on, or closed. The input voltage is applied to a voltage-holding capacitor and varactor diode. During the tracking phase, the operation is dominated by the switches. The CMOS amplifier is less active.

The transient response or intrinsic time delay is determined by the resistance-capacitance (RC) time constants associated with the primary switch (S1), voltage holding capacitor, the secondary CMOS switch (S2), and varactor capacitance or capacitance of the varactor diode. In the disclosure, there are two RC time constants. The first RC time constant is determined by the resistor of S1 (that is turned on) and the capacitance of the capacitor (CHOLD). The second RC time constant is determined by the resistor of the first switch (S1) plus the resistor of the second switch (S2) (both S1 and S2 are turned on) and the capacitance of the varactor diode (DVAR).

When the switch (S1 or S2) is in an “ON” state, the resistance value of the switches S1 and S2 is low. Therefore, the related RC time constant is low. In the “ON” state, the switches S1 and S2 are closed, such that the circuit is connected via the switches.

According to another aspect, in the holding phase, both switches are turned “off”. The CMOS unity gain buffer or amplifier is in full operation. The holding phase is a steady-state mode of operation. Under the steady-state mode of operation, the transient response is minimized such that a power dissipation is mostly DC operation current plus the leakage current of the varactor diode, which is low in the application of interest. As such, an ultra-low power may be used for the varactor driver.

According to various aspects, the disclosed varactor driver makes use of CMOS switches to control the mode of operation. As such, when in the tracking mode, the varactor driver can reduce the signal path RC time constant to achieve a fast response, when in the holding mode, the varactor driver can use an ultra-low power CMOS amplifier to reduce power dissipation.

The disclosed varactor driver has several benefits over the conventional varactor driver. The varactor driver can have a fast-transient response without a need of using a high gain amplifier. The varactor driver may use ultra-low power CMOS amplifier in operation. The varactor driver may also have a small die size.

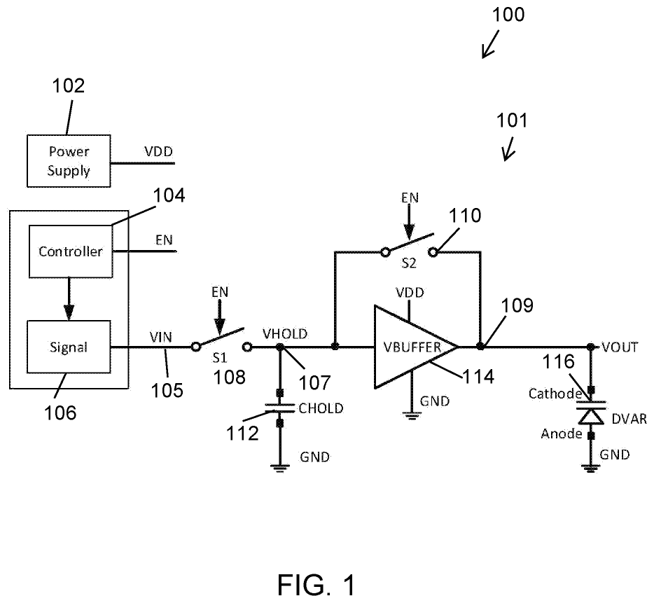

FIG. 1 is a diagram of a system including varactor driver and varactor diode according to one aspect of the disclosure. As shown in FIG. 1, a varactor driver system 100 includes a power supply 102 for providing a voltage supply, labeled as VDD.

The varactor driver system 100 also includes a varactor diode 116, labeled as DVAR. The varactor diode 116 is a type of capacitor. Unlike the conventional capacitors having constant capacitance, the capacitance value of the varactor diode 116 varies with an applied voltage. The varactor diode 116 has two terminals, i.e., Anode and Cathode. The varactor diode 116 is configured to be reversely biased. In the present application, the varactor diode 116 is the load, representing the application.

The system 100 also includes a varactor driver 101 coupled to the varactor diode 116 and provides an output voltage to the varactor diode 116. The varactor driver 101 drives the load of the varactor diode 116. The driver may have a voltage droop, which is the voltage loss, defined as a percentage of VOUT initial value over a period of time.

The system 100 also includes a controller 104 that can send a control signal labeled as EN to control the operation of each of switches S1 and S2. The controller 104 also controls the signal source 106, which provides a signal voltage VIN to the varactor driver 101.

The varactor driver 101 includes a first switch or primary switch labeled as S1, between the node of VIN (input voltage) and the node of VHOLD (holding-voltage). The varactor driver 101 also includes a second switch or secondary switch labeled as S2, between the node of VHOLD and the node of VOUT (output voltage).

The varactor driver 101 also includes a voltage-holding capacitor 112 (CHOLD), which holds an electrical potential or voltage (VHOLD) related to the charge stored in the voltage-holding capacitor 112.

The varactor driver 101 further includes an operational amplifier 114 (VBUFFER) which can make its output voltage follow the input voltage through its feedback loop operation. If the output voltage becomes low due to current leakage change, the operational amplifier or voltage buffer 114 may provide compensation current that increases the output voltage till its original level.

The operational amplifier 114 (VBUFFER) includes four terminals. For example, an input terminal connects to an input node 107, an output terminal connects to an output node 109, a power supply terminal receives supply voltage VDD from power supply source 102, and a ground terminal connects to ground (GND). The operational amplifier 114 serves two functions. First, the operational amplifier has a gain of unity, i.e., the output voltage (VOUT) equals to the input voltage (VHOLD) to the operational amplifier 114. In other words, the output voltage (VOUT) follows the input voltage (VHOLD). Second, the output node 109 is completely isolated from the input node 107 when S2 is open. In other words, the output current path is not connected to the input current path when S2 is open.

The system 100 can have a first mode and a second mode of operations or can operate in the first mode and the second mode. The first mode of operation may be a tracking mode, which is also referred to as a sampling mode. The second mode of operation may be a holding mode.

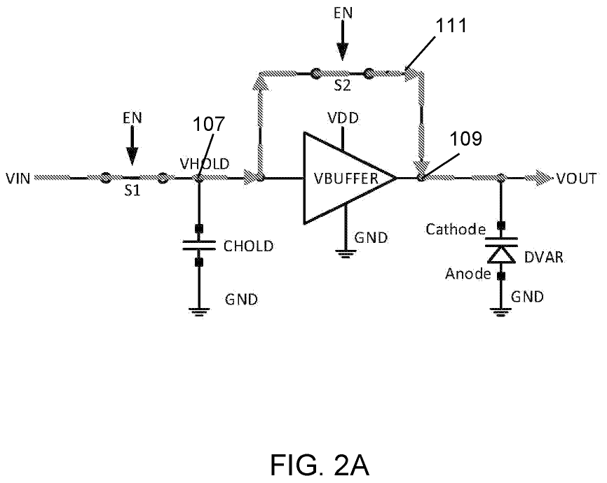

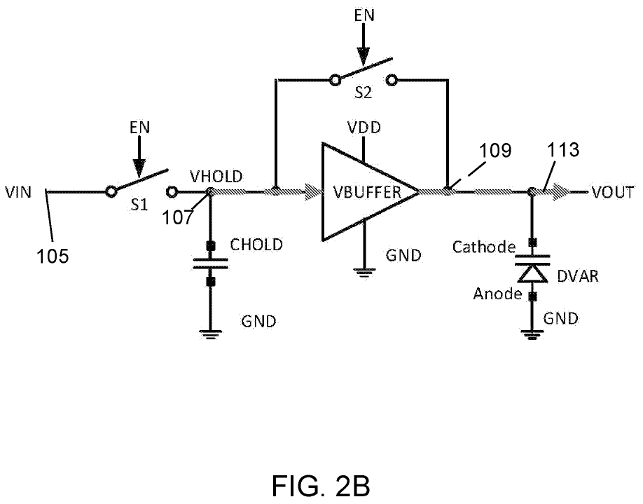

FIG. 2A illustrates a configuration of the varactor driver of FIG. 1 for operation in a tracking mode of operation according to one aspect. In the tracking mode, both the first switch S1 and the second switch S2 are closed, controlled by the control signal labeled as “EN” from the controller 104. The electric current follows arrows 111 to flow through the S1, then S2. When the first switch S1 is closed, the input node 107 or VHOLD node 107 to the VIN node 105 has a first short circuit configuration, which results Eq. (1) as follows:

$$VHOLD = VIN \qquad Equation ( 1 )$$

when the second switch S2 is closed, the output node 109 or VOUT node 109 to the VHOLD node 107 has a second short circuit configuration, which results Eq. (2) as follows:

$$VOUT = VHOLD \qquad Equation ( 2 )$$

The tracking mode has three characteristics described as follows. First, when the input voltage (VIN) at the VIN node 105 changes, both VHOLD and VOUT follow VIN with an intrinsic time delay. The characteristic of VHOLD and VOUT following the VIN is referred to as tracking.

Second, the change at the VOUT node is associated with charging both the voltage-holding capacitor 112 (CHOLD) and varactor diode 116 (DVAR). When VHOLD is applied to voltage-holding capacitor 112, voltage-holding capacitor 112 is charged. When VOUT is applied to varactor diode 116, varactor diode 116 is charged. Due to the first and second short-circuit configurations from VIN node 105 to VOUT node 109 via closed switches S1 and S2, the electrical path from VIN node 105 to VHOLD node 107 via closed S1 and then from the VHOLD node 107 to the VOUT node 109 via closed S2 has the lowest resistance for charging, as long as the input voltage VIN from the VIN node 105 provides adequate power.

Third, the short-circuit configurations also help reduce the intrinsic time delay of tracking due to the lowest resistance and thus lower RC time constant, which results in the fast response of the driver 101.

FIG. 2B illustrates a configuration of the varactor driver of FIG. 1 for operation in a holding mode of operation according to one aspect. In the holding mode, the VIN node 105 is disconnected from the rest of circuitry when the first or primary switch S1 is controlled to be open by controller 102 using control signal “EN.” The electric current follows arrows 113 to flow through the operational amplifier, which may be configured to be a unity gain buffer. The varactor diode has a voltage droop that is compensated by the unity gain buffer. The input voltage to the operational amplifier 114 (VBUFFER) is a holding-voltage VHOLD. When the second or secondary switch S2 is controlled to be open by the controller 102 via control signal “EN,” the voltage VOUT at the VOUT node 109 follows the input voltage VHOLD at the VHOLD node 107, resulting Eq. (3) as follows:

$$VOUT = VHOLD \qquad Eq . ( 3 )$$

The holding mode has three characteristics. First, as the VIN node 105 is disconnected from the rest of circuitry by opening the first switch or primary switch S1 in the holding mode, the input voltage VIN does not affect the VHOLD at the VHOLD node 107. The holding-voltage (VHOLD) remains unchanged from the previous tracking mode. The output voltage VOUT at the VOUT node 109 then follows VHOLD via the operational amplifier 114 (VBUFFER). This characteristic provides a holding-voltage for the VOUT, and is the reason for the mode of operation to be called “holding mode.”

Second, the operational amplifier 114 (VBUFFER) is more active in the holding mode than the tracking mode. The second switch or secondary switch S2 is open such that the VHOLD isolates from the VOUT, which allows the VOUT to follow VHOLD via the operational amplifier 114. The power for these operations may be supplied by VDD from the power supply source 102. Since the VHOLD voltage is a constant, the varactor driver is in a steady state in which the power dissipation is reduced compared to a tracking state.

Third, when the varactor diode 116 has a leakage current path from VOUT to GND, the operational amplifier 114 (VBUFFER) may compensate the leakage and keep VOUT from drooping. On the other hand, the operational amplifier 114 may have additional power dissipation due to VDD supplied by the power source 102.

There are several benefits of the design of the varactor driver. First, the tracking mode of operation is fast, as the closed first and second switches S1 and S2 provide the low resistive path, thus the varactor driver has a fast response. Second, the VDD power dissipation is limited as the operational amplifier 114 is mostly used during the holding mode. Third, the varactor driver includes only four components (e.g., switches S1 and S2, voltage-holding capacitor 112, operational amplifier 114, thus allows a compact die area for circuit implementation.

As an example, assume that the “ON” resistor of S1 has a resistance of 140 KΩ, the voltage-holding capacitor (CHOLD) has a capacitance of 16 pF, the RC time constant would be 2.24 μs. It will be appreciated by those skilled in the art that one may vary the RC time constant by varying the resistance and/or capacitance of the capacitor.

As another example, assume that the “ON” resistor of the second switch S2 has a resistance of 140 KΩ, the varactor diode (DVAR) has a capacitance varying from 0.4 pF to 2.5 pF, the RC time constant would range from 0.1 μs to 0.7 μs.

In some variations, the RC time constant for the varactor driver may be equal to or less than 10 μs. In some variations, the RC time constant for the varactor driver may be equal to or less than 5 μs. In some variations, the RC time constant for the varactor driver may be equal to or less than 4 μs. In some variations, the RC time constant for the varactor driver may be equal to or less than 3 μs. In some variations, the RC time constant for the varactor driver may be equal to or less than 2 μs. In some variations, the RC time constant for the varactor driver may be equal to or less than 1 μs. In some variations, the RC time constant for the varactor driver may be equal to or less than 0.5 μs. In some variations, the RC time constant for the varactor driver may be equal to or less than 0.1 μs.

According to various aspects and embodiments, the varactor driver disclosed herein can operate at a low power, for example, less than 1 μA/element at 20 V supply, or 20 μW per driver. The disclosed varactor driver can also have a reduced voltage droop rate, for example, less than 2% for 300 μs.

According to various other aspects, the disclosed array of varactor drivers (e.g., including about 50,000 drivers) may use about power of 1 Watt, which translates to a very low power per driver, i.e., 20 μW.

In some variations, the power for a varactor driver may be less than 50 μW. In some variations, the power for a varactor driver may be less than 45 μW. In some variations, the power for a varactor driver may be less than 40 μW. In some variations, the power for a varactor driver may be less than 35 μW. In some variations, the power for a varactor driver may be less than 30 μW. In some variations, the power for a varactor driver may be less than 25 μW. In some variations, the power for a varactor driver may be less than 20 μW. In some variations, the power for a varactor driver may be less than 15 μW. In some variations, the power for a varactor driver may be less than 10 μW. In some variations, the power for a varactor driver may be less than 5 μW.

In some variations, the current for a varactor driver may be equal to or less than 1.0 ρA at a voltage supply of 20 V. In some variations, the current for a varactor driver may be equal to or less than 0.8 μA at a voltage supply of 20 V.

In some variations, the voltage droop for a varactor driver may be equal to or less than 2.0% for a period of time of 300 μs. In some variations, the voltage droop for a varactor driver may be less than 1.5% for a period of time of 300 μs. In some variations, the voltage droop for a varactor driver may be less than 1.0% for a period of time of 300 μs.

Further, the varactor driver has a small die size. For example, the die size of the varactor driver may be less than 2.3 mm² for the varactor drivers.

### Example Circuit Diagrams

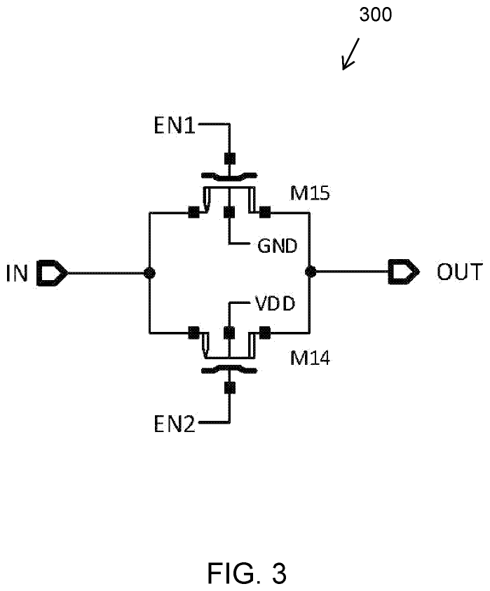

FIG. 3 illustrates a circuit diagram of a switch including NMOS and PMOS transistors according to one aspect. A CMOS switch 300 may include two MOS transistors, i.e., a NMOS (M15) and a PMOS (M14) that may be connected back-to-back as shown in FIG. 3. The switch 300 may have one input, labeled as “IN,” and one output, labeled as “OUT.” The gate of the NMOS transistor (M15) may be driven from a first control signal labeled as “EN1” while the gate of the PMOS transistor (M14) may be driven from a second control signal labeled as “EN2.” The first and second control signals EN1 and EN2 may be inverted with each other in operation.

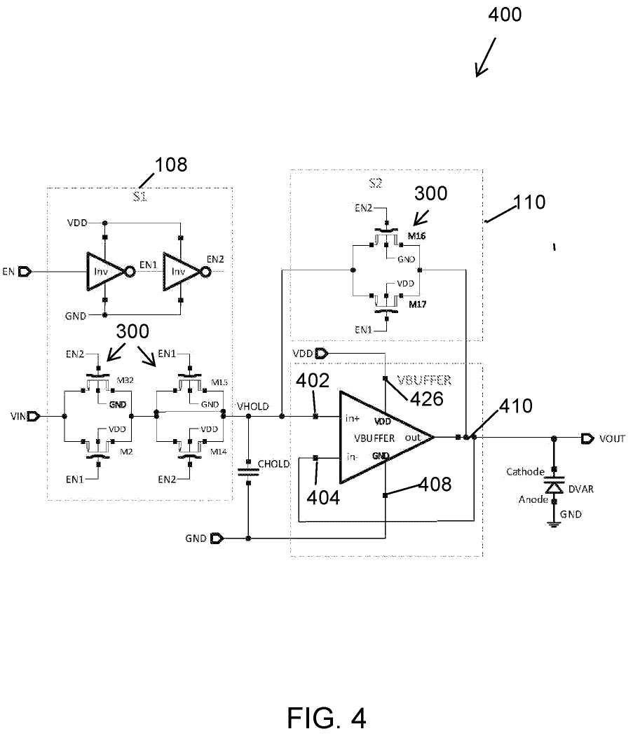

FIG. 4 illustrates a circuit diagram of the varactor driver for implementation of the operation of the tracking mode of FIG. 2A and the holding mode of FIG. 2B according to one aspect. An example varactor driver 400 includes four components, first switch 108 (S1), second switch 110 (S2), operational amplifier 114, voltage-holding capacitor 112. The first switch S1 can be constructed by using CMOS transmission gates, M32 and M2. Two inverters (labelled as Inv) may be used to form an inverted signal EN1 from EN and a non-inverted signal EN2 from EN, to control the NMOS (M32) and PMOS (M2), respectively.

NMOS transistor (M15) and PMOS transistor (M14) may be added to enhance the switching performance. M15 and M14 may form a dummy switch, to isolate the switching current effect on the capacitor (CHOLD), therefore, reducing the voltage offset between VIN and VHOLD.

The second switch (S2) may be constructed using CMOS transmission gates, NMOS (M32) and PMOS (M2). Two inverters (labelled as Inv) are used to form the inverted signal EN1 and non-inverted signal EN2 from the control signal EN, to control the NMOS (M16) and PMOS (M17), respectively.

The operational amplifier 114 may be configured to be a unity gain buffer. To do so, the input terminal 107 in FIG. 1 may be split into a non-inverting input terminal 402 and an inverting input terminal 404. The unity gain buffer may include a non-inverting input terminal 402 (in+), an inverting input terminal 404 (in−), an output terminal 410, a power supply terminal 406, and a ground terminal 408. The non-inverting input terminal 402 (in+) may connect to the capacitor 112, the first switch (S1), and the second switch (S2). The output terminal 410 may connect to the varactor diode 116. The power supply terminal 406 may connect to the power supply source 102 (VDD). The ground terminal 408 may connect to ground. The operational amplifier 114 may be configured to be the unity gain buffer by connecting the inverting input terminal 404 (in−) to the output terminal 410.

In some variations, the CMOS transistors may be metal-oxide-semiconductor-field-effect transistors (MOSFETs).

In some variations, the voltage-holding capacitor 112 (CHOLD) may be a capacitor constructed using poly-silicon material.

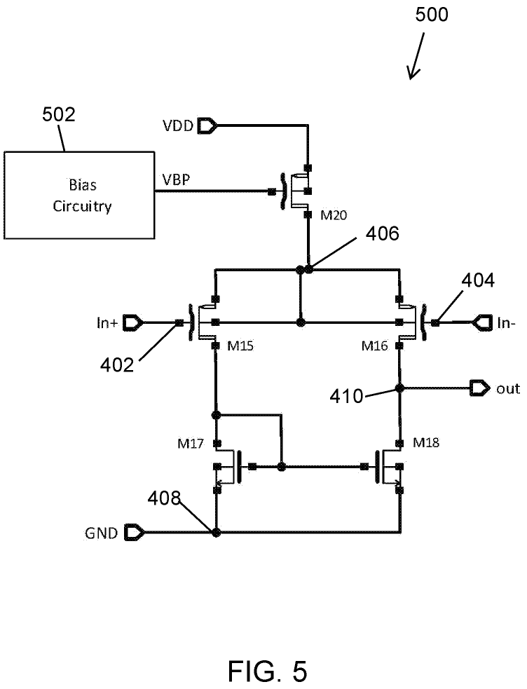

An example construction of operational amplifier 114 (VBUFFER) is provided. FIG. 5 is a circuit diagram of the operational amplifier of FIG. 4 according to one aspect. A core circuit 500 for operational amplifier 114 is a single stage operational amplifier. The core circuit 500 may include five CMOS transistors, e.g., PMOS transistor (M15), PMOS transistor (M14), NMOS transistor M17, NMOS transistor M18, and PMOS transistor M20.

The core circuit 500 may also include a bias circuitry 502, which provides an input voltage (VBP) to PMOS transistor (M20), for the operation of the operational amplifier (VBUFFER) 114.

### Example Transient Analysis

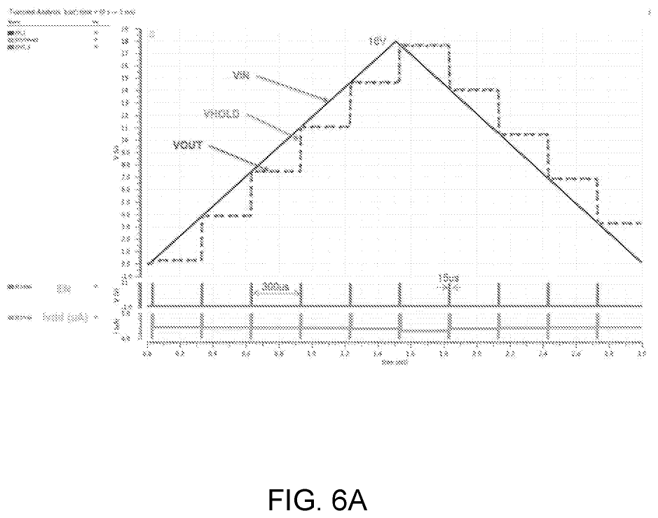

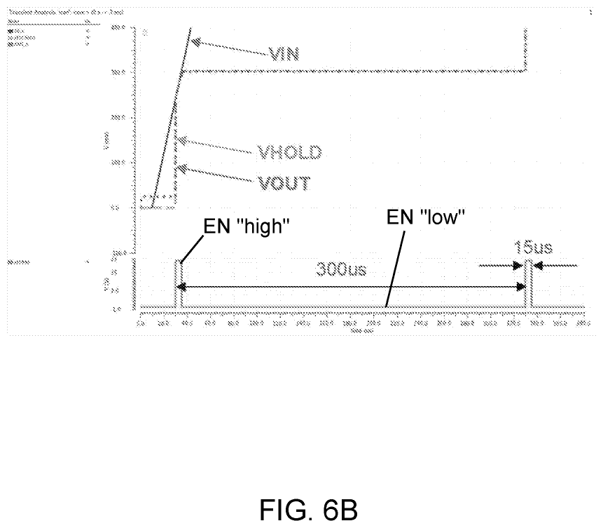

Transient analysis was performed on the varactor driver system 100 using CADENCE Electronic design automation (EDA) software. For a particular application of mobile satellite antenna, the transient analysis uses input voltage VIN varied from 0 to 18 V. Results of the transient analysis or circuit simulations are presented in FIGS. 6A-6B.

FIG. 6A shows transient voltage versus time illustrating an example of the operation of the varactor driver 400. As shown in FIG. 6A, the VIN has a triangular waveform, ramping from a low voltage to a high voltage, for example, from 0 V to 18 V.

As shown in FIG. 6A, along the horizontal axis at the bottom, the control signal “EN” includes a series of voltage pulses in volts with a constant period between two-consecutive pulses, for example, a period of 300 p s. Each pulse has a fixed pulse width, for example, a pulse width of 15 μs. The output voltage (VOUT) is a constant that holds for a period of time, for example, a period of 300 μs. The output voltage (VOUT) may increase at an increment of VHOLD provided by voltage-holding capacitor 112 (CHOLD).

During the time when the control signal “EN” is set to be “high” by controller 104, first and second switches S1 and S2 are closed. The varactor driver 400 works in a tracking mode. The tracking mode is also referred to as a sampling mode or a sampling phase. In this sampling phase, the output voltage (VOUT) is at the same value as the input voltage (VIN).

However, during the time when the control signal “EN” is set to be “low” by controller 104, the first and second switches S1 and S2 are open. The varactor driver 400 operates in a holding mode, which is also referred to as a holding phase. In the holding mode, the output voltage (VOUT) has the same value as the holding-voltage (VHOLD).

FIG. 6A also shows the power supply current Ivdd versus time. This is the total current of two drivers, plus a bias circuit and two varactor loads. Ivdd includes a series of pulses, like the control voltage signal “EN.” The Ivdd varies from 4.0 μA to 5.0 PA. Based on the transient analysis, the average current dissipation for one driver is less than 1 μA at a voltage supply of 20 V. It will be appreciated by those skilled in the art that the target value may vary with a particular application.

FIG. 6B shows an enlarged view of the transient voltage versus time illustrating an example of the operation of the varactor driver 400 of FIG. 6A. The enlarged view is a zoomed-in of the time window from starting time to 380 μs. As shown in FIG. 6B, the solid line represents the input voltage, the dots represent the output voltage (VOUT), and the dash-lines represent the holding-voltage (VHOLD). As shown, the VOUT and VHOLD have a transient response when EN is “high”. The output voltage (VOUT) of the varactor driver tracks the input voltage (VOUT=VIN) when the EN is “high”. When EN goes to “low”, the output voltage (VOUT) of the varactor driver holds the voltage value on the capacitor (VOUT=VHOLD) until the next tracking request (e.g., 300 μs later). During the time that EN is “low”, the first and second switches S1 and S2 are open. The driver operates in a holding mode. VOUT is at the same value as VHOLD.

Based on the transient analysis, the average current dissipation is less than 1 μA per driver at a voltage supply of 20 V, or 20 μW per unit. As an example, for a power supply of 1 Watt (W), an array of 50,000 drivers can be integrated with each driver having a power supply of 20 μW.

The varactor driver 101 may be used for an electronically steered, flat-panel satellite terminal for fixed and mobile platforms. The varactor driver 101 may be CMOS technology-based varactor driver. The varactor driver is also referred to as element driver.

As an example, desired target values for a particular application of the varactor driver or element driver may include a current less than 1 μA per element driver at a voltage supply of 20 V and less than 2% voltage droop for a period of time of 300 μs. Note the droop rate of less than 2% voltage droop for 300 μs is a specific criterion for an example of application. The droop rate is not a linear characteristic.

It will be appreciated by those skilled in the art that the target values of droop rates, power consumptions, response times for other applications may vary. For example, the target values including power, response time, current, voltage supply, voltage droop, and request period of time, etc., may vary.

### System Including Array of Varactor Drivers

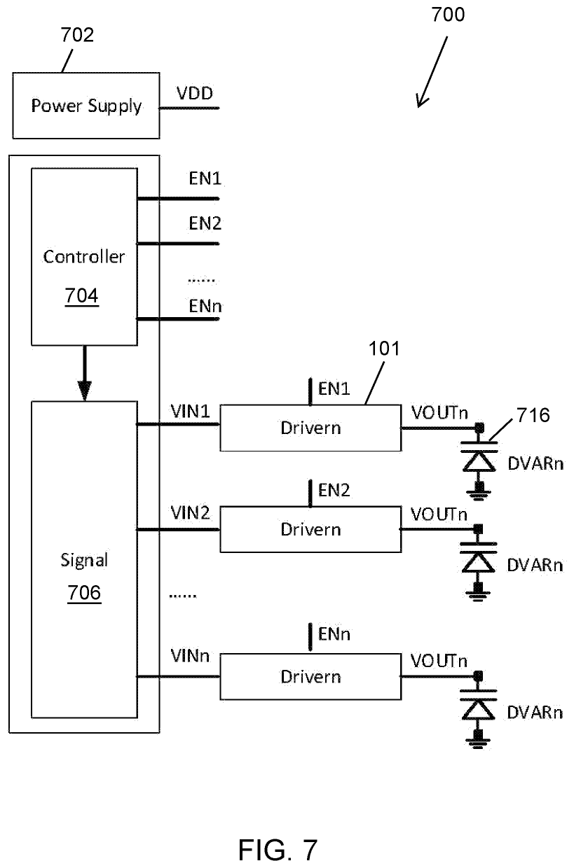

FIG. 7 is a system diagram including an array of the varactor drivers of FIG. 1 according to one aspect. A system 700 includes an array of varactor drivers 101, such as Driver-1, Driver-2, . . . Driver-n. The number of drivers “n” may vary. For example, the number of drivers may be 1,000 to 100,000. Each varactor driver 101 includes a first switch 108, a second switch 110, a capacitor 112, and an operational amplifier 114, as illustrated in FIG. 1. An example circuit diagram of the varactor driver 101 is illustrated in FIG. 4.

The system 700 may also include a controller 104 that provides a number of control signals such as EN1, EN2 . . . ENn for controlling the first and second switches in each varactor driver 101. The first and second control signals for the respective first and second switches may be inverted with each other in operation.

The system 700 may also include a power supply 702 for providing voltage supply (VDD) to the operational amplifier in each varactor driver, such as Driver-1, Driver-2, . . . Driver-n, where n is an integer.

The system 700 may also include a number of varactor diodes 716, such as DVAR-1, DVAR-2, . . . DVAR-n, where n is an integer. The system 700 also includes a signal source 706 that provides input voltages, such as VIN-1, VIN-2, . . . VIN-n, where n is an integer, to the array of varactor drivers 101, respectively. Each varactor driver 101 provides an output voltage, such as VOUT-1, VOUT-2 . . . VOUT-n to the respective varactor diodes 716. Each varactor diode may be configured to be reversely biased.

In some variations, the power for an array of varactor drivers may be less than 10.0 Watt (W). In some variations, the power for an array of varactor drivers may be less than 5.0 W. In some variations, the power for an array of varactor drivers may be less than 2.0 W. In some variations, the power for an array of varactor drivers may be less than 1.5 W. In some variations, the power for an array of varactor drivers may be less than 1.0 W. In some variations, the power for an array of varactor drivers may be less than 0.5 W. In some variations, the power for an array of varactor drivers may be less than 0.1 W.

There are various applications for the disclosed varactor driver. For example, large varactor diode arrays include an array of varactor drivers. The varactor diode array can adjust the capacitance values. Such applications can be found in the frequency tuning of mobile satellite antennas in the Ku/Ka bands. In these applications, the controller can provide control signals to each varactor driver of the array.

In some aspects, the varactor driver can be used for an electronically steered flat-panel satellite terminal for fixed and mobile platforms.

Statement 1. A varactor driver for a varactor diode, the varactor driver comprising: a first switch controlled by the control signal; a second switch controlled by the control signal, the varactor driver being configured to operate in a tracking mode when the first switch and the second switch are tuned on and to operate in a holding mode when the first switch and the second switch are tuned off; an operational amplifier connected with the second switch in parallel, wherein the operational amplifier is configured to be a unity gain buffer; and a capacitor configured to operate in the holding mode to provide a holding-voltage as an output voltage.

Statement 2. The varactor driver of statement 1, wherein the varactor driver is CMOS based.

Statement 3. The varactor driver of statement 1, wherein the first switch comprises a NMOS transistor and a PMOS transistor connected back-to-back with the NMOS transistor.

Statement 4. The varactor driver of statement 3, wherein the NMOS transistor has a gate driven by the first control signal, wherein the PMOS transistor has a gate driven by the second control signal inverted from the first control signal.

Statement 5. The varactor driver of statement 1, wherein the unity gain buffer comprises a non-inverting input terminal, an inverting input terminal, an output terminal, a power supply terminal, and a ground terminal.

Statement 6. The varactor driver of statement 5, wherein the non-inverting input terminal connects to the capacitor, the first switch, and the second switch.

Statement 7. The varactor driver of statement 5, wherein the output terminal connects to the varactor diode.

Statement 8. The varactor driver of statement 5, wherein the power supply terminal connects to a power supply source, wherein the ground terminal connects to ground.

Statement 9. The varactor driver of statement 5, wherein the operational amplifier is configured to be the unity gain buffer by connecting the inverting input terminal to the output terminal.

Statement 10. The varactor driver of statement 1, wherein the varactor diode has a voltage droop that is compensated by the unity gain buffer.

Statement 11. The varactor driver of statement 1, wherein the varactor driver has power consumption equal to or less than 50 μW.

Statement 12. The varactor driver of statement 1, wherein the varactor driver has a fast response with an RC time constant equal to or less than 10 μs.

Statement 13. The varactor driver of statement 1, wherein the operational amplifier is constructed using CMOS technology.

Statement 14. The varactor driver of statement 1, wherein the varactor driver comprises two or more varactor drivers.

Statement 15. A system comprising: the varactor driver of statement 1; a controller coupled to the varactor driver to provide the first control signal to the first switch and to provide the second control signal to the second switch; a power source coupled to the unity gain buffer; and a signal source coupled to the varactor driver through the first switch to provide an input voltage to the varactor driver.

Statement 16. A method of operating the system of statement 15, the method comprising: responding to a first tracking request comprising performing operations (1) and (2): (1) closing the first switch and the second switch, by using the controller, to operate the varactor driver in the tracking mode, wherein the second switch shorts the operational amplifier to provide a lowest resistance path to bypass the operational amplifier such that the driver has a reduced RC time constant and a reduced response time; and (2) opening the first switch and the second switch, by using the controller, to operate the varactor driver in the holding mode, wherein the driver is in a steady state.

Statement 17. The method of statement 16, wherein the first switch and the second switch are closed or turned “ON” in the tracking mode such that the output voltage equals to the input voltage in the tracking mode, wherein the first switch and the second switch are open or turned “off” in the holding mode such that the output voltage equals to the holding voltage on the capacitor in a preceding tracking request prior to the first tracking request, the unity gain buffer being fully active in the holding mode and less active in the tracking mode.

Statement 18. The method of statement 16, further comprising responding to a second tracking request by repeating operations (1) and (2) succeeding the first tracking request after a first period of time, wherein in the holding mode, the output voltage equals to the holding-voltage on the capacitor in the first tracking request.

Statement 19. The method of statement 18, further comprising responding to a third tracking request by repeating operations (1) and (2) succeeding the second tracking request after a second period of time, wherein in the holding mode, the output voltage equals to the holding-voltage on the capacitor in the second tracking request.

Statement 20. The method of statement 19, wherein the second period of time equals to the first period of time.

Statement 21. The method of statement 16, wherein the varactor diode is configured to be reversely biased.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages.

While the present disclosure has been described with reference to various embodiments, it will be understood that these embodiments are illustrative and that the scope of the disclosure is not limited to these embodiments. Many variations, modifications, additions, and improvements are possible. More generally, embodiments in accordance with the present disclosure have been described in the context of particular implementations. Functionality may be separated or combined in blocks differently in various embodiments of the disclosure or described with different terminology. These and other variations, modifications, additions, and improvements may fall within the scope of the disclosure as defined in the claims that follow.

Any ranges cited herein are inclusive. The terms “substantially” and “about” used throughout this specification are used to describe and account for small fluctuations. For example, they can refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

Having described several embodiments, it will be recognized by those skilled in the art that various modifications, alternative constructions, and equivalents may be used without departing from the spirit of the invention. Additionally, a number of well-known processes and elements have not been described in order to avoid unnecessarily obscuring the invention. Accordingly, the above description should not be taken as limiting the scope of the invention.

Those skilled in the art will appreciate that the presently disclosed embodiments teach by way of example and not by limitation. Therefore, the matter contained in the above description or shown in the accompanying drawings should be interpreted as illustrative and not in a limiting sense. The following claims are intended to cover all generic and specific features described herein, as well as all statements of the scope of the method and system which, as a matter of language, might be said to fall therebetween.

What is claimed is:

1. A varactor driver for a varactor diode load, the varactor driver comprising:
a first switch controlled by a control signal;
a second switch controlled by the control signal, the varactor driver being configured to operate in a tracking mode when the first switch and the second switch are tuned on and to operate in a holding mode when the first switch and the second switch are tuned off;
an operational amplifier connected with the second switch in parallel, wherein the operational amplifier is configured to be a unity gain buffer; and
a capacitor configured to operate in the holding mode to provide a holding-voltage as an output voltage.

2. The varactor driver of claim 1, wherein the varactor driver is CMOS based.

3. The varactor driver of claim 1, wherein the first switch comprises a NMOS transistor and a PMOS transistor connected back-to-back with the NMOS transistor.

4. The varactor driver of claim 3, wherein the NMOS transistor has a gate driven by the first control signal, wherein the PMOS transistor has a gate driven by the second control signal inverted from the first control signal.

5. The varactor driver of claim 1, wherein the unity gain buffer comprises a non-inverting input terminal, an inverting input terminal, an output terminal, a power supply terminal, and a ground terminal.

6. The varactor driver of claim 5, wherein the non-inverting input terminal connects to the capacitor, the first switch, and the second switch.

7. The varactor driver of claim 5, wherein the output terminal connects to the varactor diode.

8. The varactor driver of claim 5, wherein the power supply terminal connects to a power supply source, wherein the ground terminal connects to ground.

9. The varactor driver of claim 5, wherein the operational amplifier is configured to be the unity gain buffer by connecting the inverting input terminal to the output terminal.

10. The varactor driver of claim 1, wherein the varactor diode has a voltage droop that is compensated by the unity gain buffer.

11. The varactor driver of claim 1, wherein the varactor driver has power consumption equal to or less than 50 μW.

12. The varactor driver of claim 1, wherein the varactor driver has a fast response with an RC time constant equal to or less than 10 μs.

13. The varactor driver of claim 1, wherein the operational amplifier is constructed using CMOS technology.

14. The varactor driver of claim 1, wherein the varactor driver comprises two or more varactor drivers.

15. A system comprising:
the varactor driver of claim 1;
a controller coupled to the varactor driver to provide the control signal to the first switch and the second switch;
a power source coupled to the unity gain buffer; and
a signal source coupled to the varactor driver through the first switch to provide an input voltage to the varactor driver.

16. A method of operating the system of claim 15, the method comprising:
responding to a first tracking request comprising performing operations (1) and (2) as follows:
(1) closing the first switch and the second switch, by using the controller, to operate the varactor driver in the tracking mode, wherein the second switch shorts the operational amplifier to provide a lowest resistance path to bypass the operational amplifier such that the driver has a reduced RC time constant and a reduced response time; and
(2) opening the first switch and the second switch, by using the controller, to operate the varactor driver in the holding mode, wherein the driver is in a steady state.

17. The method of claim 16, wherein the first switch and the second switch are closed or turned “ON” in the tracking mode such that the output voltage equals to the input voltage in the tracking mode, wherein the first switch and the second switch are open or turned “off” in the holding mode such that the output voltage equals to the holding-voltage on the capacitor in a preceding tracking request prior to the first tracking request, wherein the unity gain buffer is fully active in the holding mode and less active in the tracking mode.

18. The method of claim 16, further comprising responding to a second tracking request by repeating operations (1) and (2) succeeding the first tracking request after a first period of time, wherein in the holding mode, the output voltage equals to the holding-voltage on the capacitor in the first tracking request.

19. The method of claim 18, further comprising responding to a third tracking request by repeating operations (1) and (2) succeeding the second tracking request after a second period of time, wherein in the holding mode, the output voltage equals to the holding-voltage on the capacitor in the second tracking request.

20. The method of claim 19, wherein the second period of time equals to the first period of time.

21. The method of claim 16, wherein the varactor diode is configured to be reversely biased.
